(19) United States
(12) Patent Application Publication
(10) Pub. No.: US 2014/0352616 A1
(43) Pub. Date: Dec. 4, 2014

(54) CRUCIBLE APPARATUS AND DEPOSITION APPARATUS WITH THE SAME

(71) Applicant: Samsung Display Co., Ltd., Yongin-City (KR)

(72) Inventors: Su-Hwan Lee, Asan-si (KR); Mu-Hyun Kim, Yongin-si (KR); Eun-Ho Kim, Cheonan-si (KR)

(21) Appl. No.: 14/185,246

(22) Filed: Feb. 20, 2014

(30) Foreign Application Priority Data
May 31, 2013 (KR) 10-2013-0062924

(51) Int. Cl. C23C 14/24; C23C 14/14; B05C 5/00; C23C 14/12

(52) U.S. Cl. CPC C23C 14/243; C23C 14/12; C23C 14/14; B05C 5/001
USPC 118/720; 239/135

(57) ABSTRACT

A crucible apparatus comprises: a crucible having an opening, the crucible being configured to store an organic material; a heating device surrounding the exterior of the crucible, the heating device being configured to provide heat to the crucible; at least one thermal ball configured to deliver the heat provided by the heating device to the organic material within the crucible so as to sublimate the organic material; and at least one spray nozzle disposed at the opening of the crucible and configured to spray the sublimated organic material.

This application claims priority from and the benefit of Korean Patent Application No. 10-2013-0062924, filed on May 31, 2013, which is hereby incorporated by reference for all purposes as if fully set forth herein.

### BACKGROUND OF THE INVENTION

1. Field of the Invention

The present invention relates to a crucible apparatus and a deposition apparatus. More particularly, the present invention relates to a crucible apparatus including thermal balls and a deposition apparatus with the crucible apparatus.

2. Description of the Related Art

An organic light emitting element used for an organic light emitting display device is a self-light emitting element which has an organic light emitting layer formed between two electrodes. In the organic light emitting display device, electrons and holes are injected into the organic light emitting layer from an electron injection electrode and a hole injection electrode, respectively. The injected electrons and holes are combined to generate excitons, which illuminate when converting from an excited state to a ground state. Since the organic light emitting display device includes the self-light emitting element, the organic light emitting display device does not need a separate light source, and volume and weight of the organic light emitting display device may be reduced compared to a liquid crystal display device. Accordingly, the organic light emitting display device is drawing attention as a flat display device.

In general, the organic light emitting layer of the organic light emitting element includes a plurality of functional layers (e.g., a hole injection layer, a hole transport layer, a light emitting layer, an electron transport layer, an electron injection layer, etc.), and the performance of the organic light emitting display element is improved by the combination and arrangement of these functional layers.

In the manufacture of the organic light emitting display element having the above composition, electrode layers and organic light emitting layers may be formed by depositing metal materials or organic materials on a substrate using a thermal vacuum deposition process.

The electrode layers and the organic light emitting layers may be formed by the thermal vacuum deposition process. Metal materials or organic materials which may form the electrode layers or the organic light emitting layers are placed in a crucible including a heating device that may heat the body of the crucible. In a vacuum chamber, when the heating device included in the crucible is operated to heat the body of the crucible, the metal materials or the organic materials in the crucible may be sublimated by the heat. The sublimated metal materials and the sublimated organic materials may be emitted through an outlet of the crucible. The electrode layers and the organic light emitting layers may be formed by selectively depositing the metal materials and the organic materials on the substrate through a mask having a plurality of openings on a top of the outlet of the crucible.

The crucible used in the thermal vacuum deposition process has a feature in that it is heated at high temperature by the heating device. Thus, it is desirable that the crucible be formed of a material that is not transformed at high temperature, efficiently delivers the heat to source materials in the crucible, and is light in weight for cleaning after the thermal vacuum deposition process. Typically, the crucible is formed of one of ceramic, titanium and graphite.

If organic materials are used in small amount, such as dopant, to form the organic light emitting layer, the organic materials cannot be spread uniformly in a large-capacity crucible. When the organic materials are not uniformly filled in the crucible, the amount of the sublimated organic materials will be different according to the position of the crucible. For example, the amount of the sublimated organic materials in a position where relatively more organic materials are filled may be greater than the amount of sublimated organic materials in a position where relatively less organic materials are filled. Furthermore, if the organic materials are not uniformly filled in the crucible, the heat may not be uniformly transferred to the organic materials. Accordingly, the organic light emitting layer may not be formed uniformly because the amounts of the sublimated organic materials are different according to the amount of the filled organic materials.

Furthermore, after forming the electrode layer using the metal materials, a crack may occur in the crucible during a cooling process for ventilation or cleaning because thermal expansion coefficients of the metal materials that remain in the crucible are different from the expansion coefficient of the crucible. To prevent this, an additional process may be further performed to remove the remaining materials in the crucible. However, this additional process increases tact time of processes, and the crucible still has the risk of getting a crack because of the remaining materials that are not eliminated in the crucible.

### SUMMARY OF THE INVENTION

Exemplary embodiments of the invention provide a crucible apparatus and a deposition apparatus for providing organic materials stably.

Exemplary embodiments of the invention also provide a crucible apparatus and a deposition apparatus for providing metal materials stably and for preventing a crack of the crucible when the crucible is cooled down.

According to one aspect of the invention, there is provided a crucible apparatus including a crucible having an opening, the crucible being configured to store an organic material, a heating device surrounding the outside of the crucible, the heating device being configured to provide heat to the crucible, at least one thermal ball configured to deliver the heat provided by the heating device to the organic material within the crucible so as to sublimate the organic material, and a spray nozzle disposed at the opening of the crucible, the spray nozzle being configured to spray the sublimated organic material.

In exemplary embodiments, the thermal ball(s) may be distributed in the crucible along with the organic material.

In exemplary embodiments, the spray nozzle may be disposed on a top of the crucible and the spray nozzle may be configured to move in a length direction or a width direction of the crucible apparatus.

According to another aspect of the invention, there is provided an organic material deposition apparatus including a deposition chamber having a space into which a substrate is inserted, a supporting member configured to support the substrate, a mask disposed under the substrate and configured to allow an organic material to be selectively deposited on the substrate, and a crucible apparatus disposed opposite the substrate, the crucible apparatus including at least one thermal ball.

In exemplary embodiments, the crucible apparatus may include a crucible having an opening, the crucible being configured to store an organic material, a heating device surrounding the outside of the crucible, the heating device being configured to provide heat to the crucible, at least one thermal ball being configured to deliver the heat provided by the heating device to the organic material within the crucible so as to sublimate the organic material, and a spray nozzle disposed at the opening of the crucible, the spray nozzle being configured to spray the sublimated organic material.

In exemplary embodiments, the thermal ball may be distributed in the crucible along with the organic material.

In exemplary embodiments, the spray nozzle may be disposed on a top of the crucible and the spray nozzle may be configured to move in a length direction or a width direction of the crucible apparatus.

According to another aspect of exemplary embodiments, a crucible apparatus includes a crucible having an opening, the crucible being configured to store a metal material, a heating device surrounding the outside of the crucible, the heating device being configured to provide heat to the crucible so as to sublimate the metal material, at least one first thermal ball disposed on a top of the crucible, the first thermal ball(s) being configured to maintain an internal temperature of the crucible, a mesh member having an opening for passing the sublimated metal material, the mesh member being configured to support the first thermal ball(s), at least one second thermal ball disposed between the crucible and the metal material in the crucible and a spray nozzle disposed at the opening of the crucible, the spray nozzle being configured to spray the sublimated metal material.

In exemplary embodiments, the second thermal ball(s) may be disposed between a bottom of the crucible and the metal material in the crucible.

In exemplary embodiments, the crucible apparatus may further include at least one third thermal ball, the second thermal ball(s) being disposed between a bottom of the crucible and the metal material in the crucible, and the third thermal ball(s) being disposed between an inner wall of the crucible and the metal material in the crucible.

In exemplary embodiments, the spray nozzle may be disposed on the top of the crucible and the spray nozzle may be configured to move in a length direction or a width direction of the crucible apparatus.

According to another aspect of the invention, a metal material deposition apparatus includes a deposition chamber having a space into which a substrate is inserted, a supporting member configured to support the substrate, a mask disposed under the substrate and configured to allow a metal material to be selectively deposited on the substrate, and a crucible apparatus disposed opposite the substrate, the crucible apparatus including at least one first thermal ball and at least one second thermal ball.

In exemplary embodiments, the metal material deposition apparatus includes a crucible having an opening, the crucible being configured to store a metal material, a heating device surrounding the outside of the crucible, the heating device being configured to provide heat to the crucible so as to sublimate the metal material, at least one first thermal ball disposed on a top of the crucible, the first thermal ball(s) being configured to keep an internal temperature of the crucible, a mesh member having an opening for passing the sublimated metal material, the mesh member being configured to support the first thermal ball(s), at least one second thermal ball disposed between the crucible and the metal material in the crucible, and a spray nozzle disposed at the opening of the crucible, the spray nozzle being configured to spray the sublimated metal material.

In exemplary embodiments, the second thermal ball(s) may be disposed between a bottom of the crucible and the metal material in the crucible.

In exemplary embodiments, the metal material deposition apparatus may further include at least one third thermal ball, the second thermal ball(s) being disposed between a bottom of the crucible and the metal material in the crucible, and the third thermal ball(s) being disposed between an inner wall of the crucible and the metal material in the crucible.

In exemplary embodiments, the spray nozzle may be disposed on the top of the crucible and the spray nozzle may be configured to move in a length direction or a width direction of the crucible apparatus.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIG. 1 is a perspective view illustrating a crucible apparatus according to an exemplary embodiment of the invention.

FIG. 2 is a cross-sectional view of the crucible apparatus illustrated in FIG. 1.

FIG. 3 is a perspective view illustrating an organic material deposition apparatus according to an exemplary embodiment of the invention.

FIG. 4 is a cross-sectional view of the organic material deposition apparatus illustrated in FIG. 3.

FIG. 5 is a perspective view illustrating a crucible apparatus according to an exemplary embodiment of the invention.

FIG. 6 is a cross-sectional view of the crucible apparatus illustrated in FIG. 5.

FIG. 7 is a perspective view illustrating a metal material deposition apparatus according to an exemplary embodiment of the invention.

FIG. 8 is a cross-sectional view of the metal material deposition apparatus illustrated in FIG. 7.

FIG. 9 is a perspective view illustrating a crucible apparatus according to an exemplary embodiment of the invention.

FIG. 10 is a cross-sectional view of the crucible apparatus illustrated in FIG. 9.

FIG. 11 is a perspective view illustrating a metal material deposition apparatus according to an exemplary embodiment of the invention.

FIG. 12 is a cross-sectional view of the metal material deposition apparatus illustrated in FIG. 11.

### DETAILED DESCRIPTION OF THE INVENTION

Various exemplary embodiments will be described more fully hereinafter with reference to the accompanying drawings, in which some exemplary embodiments are shown. The present inventive concept may, however, be embodied in many different forms and should not be construed as being limited to the exemplary embodiments set forth herein. Rather, these exemplary embodiments are provided so that this disclosure will be thorough and complete, and will fully convey the scope of the present invention to those skilled in the art. In the drawings, the sizes and relative sizes of layers and regions may be exaggerated for clarity. Like reference numerals refer to like elements throughout.

It will be understood that, although the terms first, second, third etc. may be used herein to describe various elements, these elements should not be limited by these terms. These terms are used to distinguish one element from another. Thus, a first element discussed below could be termed a second element without departing from the teachings of the present inventive concept. As used herein, the term “and/or” includes any and all combinations of one or more of the associated listed items.

It will be understood that, when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular exemplary embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art, and should not be interpreted in an idealized or overly formal sense unless expressly so defined herein.

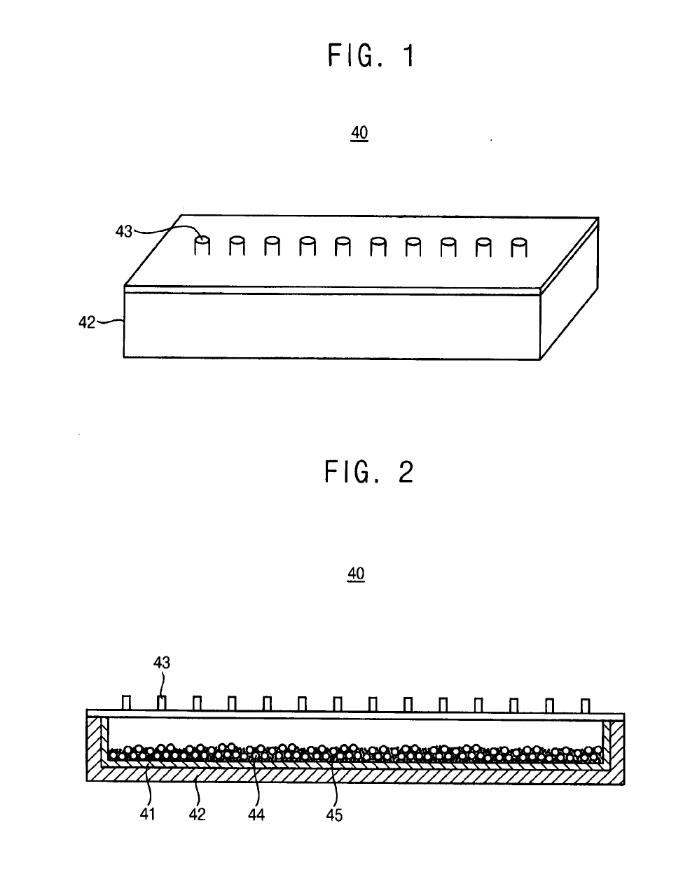

FIG. 1 is a perspective view illustrating a crucible apparatus according to an exemplary embodiment of the invention, and FIG. 2 is a cross-sectional view of the crucible apparatus illustrated in FIG. 1.

Referring to FIGS. 1 and 2, the crucible apparatus 40 may include a crucible 41, a heating device 42, spray nozzle(s) 43, thermal ball(s) 44 and an organic material 45.

The crucible 41 has an opening which passes sublimated or evaporated gas from the organic material 45 in the crucible 41. The crucible 41 may be manufactured in various shapes, such as a circle, an ellipse, a hexagon, etc. according to the shape of a substrate, a mask or a chamber in which the process is performed.

The crucible 41 may be manufactured by materials having high thermal conductivity to perform efficient heat conduction and having high durability at high temperature. In some exemplary embodiments, the crucible 41 may be manufactured by one material, such as ceramic, titanium, graphite, boron nitride (PBN), tantalum, or the like.

In other exemplary embodiments, the crucible 41 may have a double structure using two or more materials selected from ceramic, titanium, graphite, boron nitride (PBN) or tantalum to improve efficiency of heat conduction, insulation property, durability and convenience of cleaning.

The heating device 42 may surround the outside of the crucible 41. In a thermal deposition process, it is desirable that the internal temperature of the crucible 41 be maintained constantly so as to maintain a uniform deposition rate of the organic material 45. The heat provided by the heating device 42 may be delivered to the crucible 41.

In some exemplary embodiments, the heating device 42 may be comprised of a heating line. The heating line may be supplied with power from an external power supply so as to generate the heat. In other exemplary embodiments, the heating device 42 may be comprised of a pipe in which hot water or gas is circulated.

At least one spray nozzle 43 may be disposed at the opening of the crucible 41. The spray nozzle(s) 43 may control the deposition rate of the organic material 45 which is sublimated or evaporated from the crucible 41 by changing a progress direction of the sublimated organic material 45.

In some exemplary embodiments, the spray nozzle(s) 43 may have a moving device (not shown) and may be moved in a length direction or a width direction. In other exemplary embodiments, the spray nozzle(s) 43 may have a rotation device (not shown) and may be tilted to change the progress direction of the sublimated organic material 45. Thus, the spray nozzle(s) 43 may improve the deposition uniformity of the organic material 45 by spraying the organic material 45 on desired positions.

As described above, the heat may be delivered to the organic material 45 in the crucible 41 so as to deposit the organic material 45 on a substrate. When a small amount of the organic material 45 like dopant is used in a deposition process, the organic material 45 may not be spread evenly in a large-capacity crucible 41. For example, when the small amount of the organic material 45 is distributed in the crucible 41, considerable amounts of the organic material 45 may be stacked on a certain bottom area of the crucible 41, and few or no amounts of the organic material 45 may be on the other area of the crucible 41. Thus, the amount of the sublimated organic material 45 may be different according to the position of the crucible 41, and a deposition layer may not be uniformly formed on the substrate.

In order to prevent this, thermal ball(s) 44 may be distributed in the crucible 41 along with the organic material 45. The thermal ball(s) 44 may spread evenly on bottom of the crucible 41 because it is ball-shaped. The organic material 45 may be distributed evenly because powder-type organic materials may be penetrated among the thermal ball(s) 44. Furthermore, the heat from the crucible 41 may be delivered to the organic material 45 through the thermal ball(s) 44, and thus the heat transferred to the organic material 45 may have a uniform temperature.

The thermal ball(s) 44 may be formed by materials having high thermal conductivity and not responding with the organic material 45. For example, the thermal ball(s) 44 may be formed by conductive materials such as ceramic, titanium, graphite, etc.

A size of the thermal ball(s) 44 is not limited, but the number of the thermal ball(s) 44 may be enough to form a certain height of a layer on the bottom of the crucible 41. When the size of the thermal ball(s) 44 is too large, the necessary number of the thermal ball(s) 44 for forming a layer on the bottom of the crucible 41 is small. However, the organic material 45 may be agglomerated unevenly because the space among thermal ball(s) 44 is too large. In this case, the organic material 45 may not be spread evenly on the bottom of the crucible 41, and it is hard to form a uniform organic layer on the substrate because the sublimating quantity of the organic material 45 is different according to the position on which the organic material 45 is spread.

On the other hand, when the size of the thermal ball(s) 44 is too small, it is hard for the organic material 45 to penetrate the space among thermal ball(s) 44 because too small a space is formed. Furthermore, when the size of thermal ball(s) 44 is too small, the necessary number of the thermal ball(s) 44 to form a certain height of layer on the bottom of the crucible 41 may be large. Thus, the manufacturing cost of the thermal ball(s) 44 is increased, and it is difficult to manage a large number of thermal ball(s) 44. Thus, the size of the thermal ball(s) 45 may be selected considering the size of the organic material 45 and the process cost.

The organic material 45 may be selected from all materials which form an organic layer. When the organic material 45 is fulfilled with a sufficient amount in the crucible 41, the organic material 45 may be spread evenly in the crucible 41 and the heat from the crucible 41 may be effectively delivered to the organic material 45. Thus, an organic layer having uniform thickness may be formed on the substrate without the thermal ball(s) 44.

However, when a small amount of the organic material 45 like dopant is provided in the crucible 41, the organic material 45 may be spread evenly by being distributed along with the thermal ball(s) 44. In addition, the heat from the crucible 41 may be effectively delivered to the organic material 45 through the thermal ball(s) 44. Thus, uniform thickness of the organic layer may be achieved using the thermal ball(s) 44.

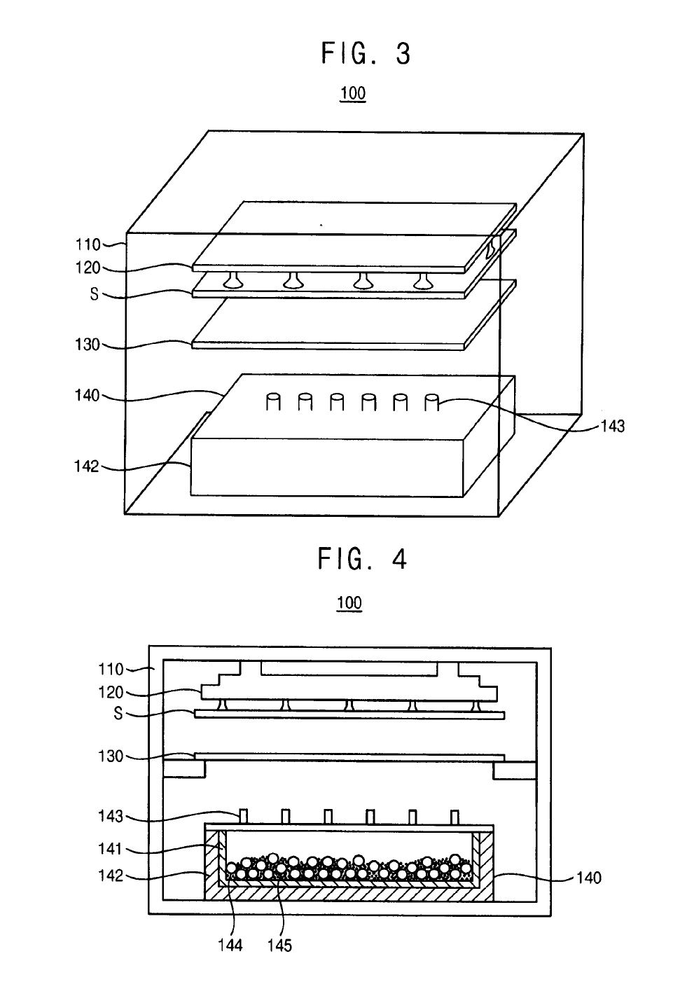

FIG. 3 is a perspective view illustrating an organic material deposition apparatus according to an exemplary embodiment of the invention, and FIG. 4 is a cross-sectional view of the organic material deposition apparatus illustrated in FIG. 3.

Referring to FIGS. 3 and 4, the organic material deposition apparatus 100 may include a deposition chamber 110, a supporting member 120, a substrate S, a mask 130 and a crucible apparatus 140.

The deposition chamber 110 provides a process space in which the organic material 145 may be deposited on the substrate S. An inner space of the deposition chamber 110 may be maintained in a vacuum state by connection to a vacuum pump (not shown) and a door (not shown) may be arranged on the side of the deposition chamber 110 for inserting and removing the substrate S. As shown in FIGS. 3 and 4, the deposition chamber 110 may be manufactured in a box shape, but it may be formed according to the shape of the substrate S.

Furthermore, the deposition chamber 110 includes the supporting member 120 which may support and transport the substrate S on which the organic material 145 may be deposited. The supporting member 120 may be mounted on the top of the deposition chamber 110, and may support the substrate S. A bottom of the substrate S on which the organic material 145 will be deposited may be disposed opposite the bottom of the deposition chamber 110. Furthermore, the supporting member 120 may comprise a transporting device (not shown) for transporting the substrate S.

The mask 130 has a patterned opening which defines an area for forming a pattern on the substrate S. An organic layer having the desired pattern may be formed by spraying the organic material 145 onto the substrate S through the mask 130.

The mask 130 may be fixed between the substrate S and the crucible apparatus 140 with additional devices in the deposition chamber 110.

The organic material deposition apparatus 100 may include the crucible apparatus 140 disposed on the bottom of the deposition chamber 110 opposite the mask 130.

The crucible apparatus 140 may include a crucible 141, a heating device 142, spray nozzle(s) 143, thermal ball(s) 144, and an organic material 145.

As described, the crucible 141 may be manufactured by use of a material having high thermal conductivity, high durability and not responding with the organic material 145. The heating device 142 may have a structure that surrounds the crucible 141, and may provide the heat to the crucible 141. Furthermore, the spray nozzle(s) 143 may control the deposition rate on the substrate S by changing a process direction of the sublimated organic material 145.

When a small amount of the organic material 145 is placed in the crucible 141, the thermal ball(s) 144 may be distributed along with the organic material 145 in the crucible 141. The thermal ball(s) 144 allow the organic material 145 to spread evenly on the bottom of the crucible 141. Furthermore, the thermal ball(s) 144 allow the heat from the crucible 141 to be effectively delivered to the organic material 145.

As described, by depositing the organic material 145 on the substrate S using the crucible apparatus 140 including the thermal ball(s) 144, the organic material 145 may be spread evenly in the crucible 141, and the heat from the crucible 141 may be effectively delivered to the organic material 145. Thus, a uniform thickness of an organic layer may be formed using the thermal ball(s) 144 because the amount of the sublimated organic material may be the same with any position of the crucible 141.

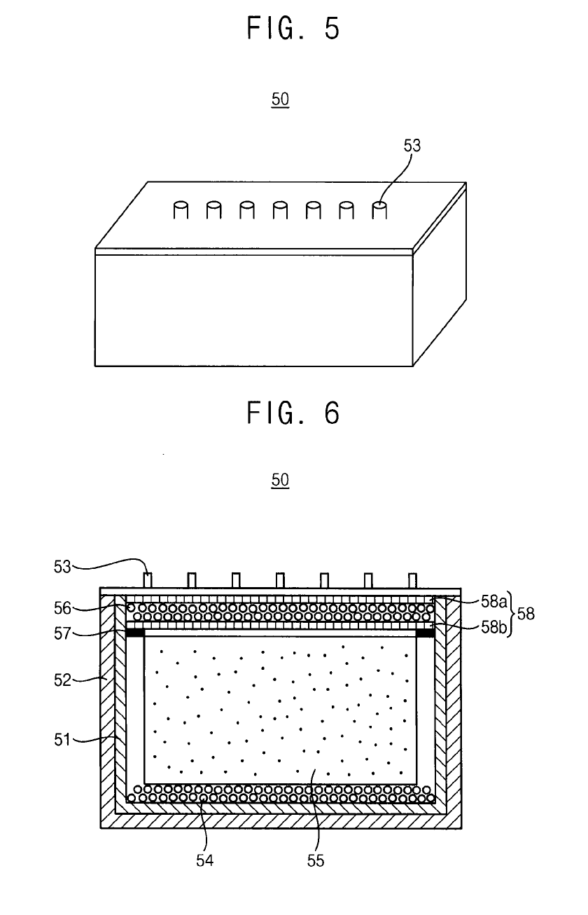

FIG. 5 is a perspective view illustrating a crucible apparatus according to an exemplary embodiment of the invention, and FIG. 6 is a cross-sectional view of the crucible apparatus illustrated in FIG. 5.

Referring to FIGS. 5 and 6, the crucible apparatus 50 may include a crucible 51, a heating device 52, spray nozzle(s) 53, first thermal ball(s) 56, second thermal ball(s) 54, mesh member 58, and a metal material 55.

The crucible 51 has an opening which passes sublimated or evaporated gas from the metal material 55 in the crucible 51. The crucible 51 may be manufactured in various shapes, such as a circle, an ellipse, a hexagon, etc, according to the shape of a substrate, a mask or a chamber in which the process is performed.

The crucible 51 may be manufactured by materials having high thermal conductivity to perform efficient heat conduction and having high durability at high temperature. In some exemplary embodiments, the crucible 51 may be manufactured by one of several materials such as ceramic, titanium, graphite, boron nitride (PBN), tantalum, or the like.

In other exemplary embodiments, the crucible 51 may have a double structure using two or more materials selected from ceramic, titanium, graphite, boron nitride (PBN) or tantalum so as to improve efficiency of heat conduction, insulation property, durability and convenience of cleaning.

The heating device 52 may surround the outside of the crucible 51. In a thermal deposition process, it is desirable that the internal temperature of the crucible 51 be maintained constantly so as to maintain a uniform deposition rate of the metal material 55. The heat provided by the heating device may be delivered to the crucible 41.

In some exemplary embodiments, the heating device 52 may be comprised of a heating line. The heating line may be supplied with power from an external power supply so as to generate the heat. In other exemplary embodiments, the heating device 52 may be comprised of a pipe in which hot water or gas is circulated.

At least one spray nozzle 53 may be disposed at the opening of the crucible 51. The spray nozzle(s) 53 may control the deposition rate of the metal material 55 which is sublimated or evaporated from the crucible 51 by changing a progress direction of the sublimated metal material 55.

In some exemplary embodiments, the spray nozzle(s) 53 may have a moving device (not shown), and may be moved in a length direction or a width direction. In other exemplary embodiments, the spray nozzle(s) 53 may have a rotation device (not shown) and may be tilted to change the progress direction of the sublimated metal material 55. Thus, the spray nozzle(s) 53 may improve the deposition uniformity of the metal material 55 by spraying the metal material 55 on desired positions.

The first thermal ball(s) 56 may be disposed on top of the crucible 51, and may be surrounded by a first mesh member 58a which is disposed on the first thermal ball(s) 56, and by a second mesh member 58b which is beneath the first thermal ball(s) 56.

The first thermal ball(s) 56 and the mesh member 58 maintain a temperature at the opening of the crucible 51. The first thermal ball(s) 56 and the mesh member 58 may prevent the heat from escaping to the exterior of the crucible 51. Thus, the substrate and the mask, which are above the crucible 51, may not be influenced by the heat from the crucible 51. Furthermore, the internal temperature of the crucible 51 may be maintained without heat loss.

The size of the first thermal ball(s) 56 is not limited, but the number of the first thermal ball(s) 56 may be enough to form a certain height of a layer at the opening of the crucible 51. When the size of the first thermal ball(s) 56 is too small, a path for the sublimated metal material 55 may be blocked by a small space formed among the first thermal ball(s) 56. Thus, the size of the first thermal ball(s) 56 may be selected according to the size of the sublimated metal material 55.

The first thermal ball(s) 56 may be formed by materials having high thermal conductivity and not responding with the metal material 55. For example, the first thermal ball(s) 54 may be formed by conductive materials such as ceramic, titanium, graphite, etc.

The first mesh member 58a may fix the first thermal ball(s) 56 and the second mesh member 58b may support the first thermal ball(s) 56. The first mesh member 58a and the second mesh member 58b are manufactured with openings for passing the sublimated metal material 55. Furthermore, the first mesh member 58a may be dropped according to the structure of the crucible 51 and manufacturing cost.

The first mesh member 58a and the second mesh member 58b may be formed by materials having high thermal conductivity and not responding with the metal material 55. For example, the mesh members 58 may be formed by conductive materials such as ceramic, titanium, graphite, etc.

After a deposition process of the metal material 55, the metal material 55 in the crucible 51 may be eliminated for chamber ventilation or device cleaning. A crack may occur in the bottom of the crucible 51 when the crucible 51 is cooled down to eliminate the metal material 55. The crack occurs due to the difference between the thermal expansion coefficient of the crucible 51 and that of the metal material 55 which remains in the crucible 51. Because the shrinkage rate of the crucible 51 and the metal material 55 are different at the same temperature, the crack may occur at the contact area of the crucible 51 and the metal materials 55. The crack may be the cause of a cost increase and a process loss by changing facilities.

To prevent this, the second thermal ball(s) 54 may be disposed on the bottom of the crucible 51. Because the second thermal ball(s) 54 is (are) disposed between the crucible 51 and the metal material 55, the crack occurring due to the difference between thermal expansion coefficients of the crucible 51 and the metal material 55 may be prevented.

Furthermore, the second thermal ball(s) 54 is (are) formed by the material having high thermal conductivity, and deliver(s) the heat to the metal material 55 constantly and stably.

The second thermal ball(s) 54 may be formed by materials having high thermal conductivity and not responding with the metal material 55. For example, the second thermal ball(s) 54 may be formed by conductive materials such as ceramic, titanium, graphite, etc.

The size of the second thermal ball(s) 54 is not limited, but the number of the second thermal ball(s) 54 may be enough to form a certain height of a layer on the bottom of the crucible 51. The size and the number of the second thermal ball(s) 54 may be selected according to the size of the crucible 51 and process cost.

The metal material 55 may be selected from all materials which form an electrode layer. In general, aluminum (Al) or magnesium (Mg) is used, and they are load type, pellet type or powder type according to form.

When the load type is used for the metal material 55 and when the thermal expansion coefficients of the crucible 51 and the metal material 55 are different, the crucible apparatus 50 including the second thermal ball(s) 54 may be used. Furthermore, a fixing member 57 may be disposed between the second mesh member 58b and the load type metal material 55 so as to prevent movement of the metal material 55.

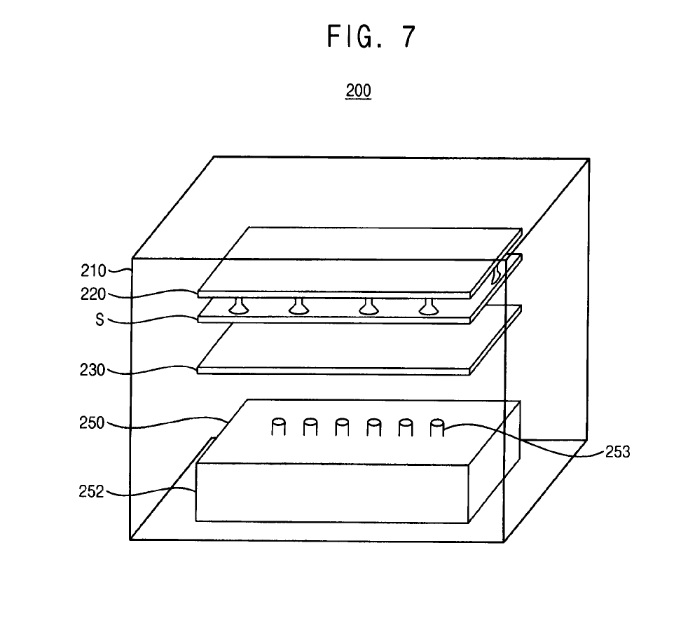

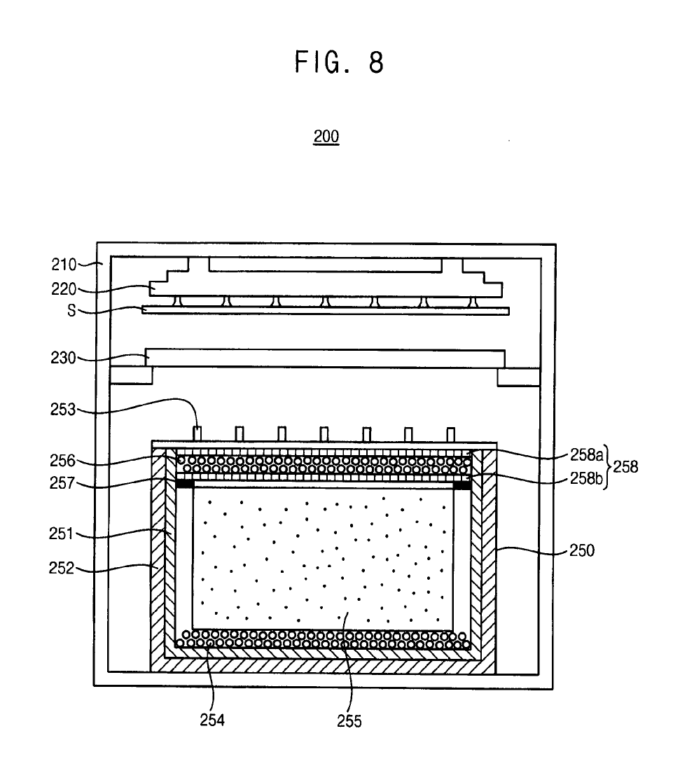

FIG. 7 is a perspective view of a metal material deposition apparatus according to an exemplary embodiment of the invention, and FIG. 8 is a cross-sectional view of the metal material deposition apparatus illustrated in FIG. 7.

Referring to FIGS. 7 and 8, the metal material deposition apparatus 200 may include a deposition chamber 210, a supporting member 220, substrate S, a mask 230 and a crucible apparatus 250.

The deposition chamber 210 provides a process space in which the metal material 255 may be deposited on the substrate S. An inner space of the deposition chamber 110 may be maintained in a vacuum state by connection to a vacuum pump (not shown), and a door (not shown) may be arranged on the side of the deposition chamber 210 for inserting and removing the substrate S. As shown in FIGS. 7 and 8, the deposition chamber 210 may be manufactured in a box shape, but it may be formed according to the shape of the substrate S.

Furthermore, the deposition chamber 210 includes the supporting member 220 which may support and transport the substrate S on which the metal material 255 may be deposited. The supporting member 220 may be mounted on the top of the deposition chamber 210, and may support the substrate S. A bottom of the substrate S, on which the metal material 255 will be deposited, may be disposed opposite the bottom of the deposition chamber 210, in other words, opposite the spray nozzle(s) 253. Furthermore, the supporting member 220 may comprise a transporting device (not shown) for transporting the substrate S.

The mask 230 has a patterned opening which defines an area for forming a pattern on the substrate S. A metal layer having a desired pattern may be formed by spraying the metal material 255 onto the substrate S through the mask 230.

The mask 230 may be fixed between the substrate S and the crucible apparatus 250 with additional devices in the deposition chamber 210.

The metal material deposition apparatus 200 may include the crucible apparatus 250 disposed on the bottom of the deposition chamber 210 opposite the mask 230.

The crucible apparatus 250 may include a crucible 251, a heating device 252, spray nozzle(s) 243, first thermal ball(s) 256, second thermal ball(s) 254, a mesh member 258 and a metal material 255.

As described above, the crucible 251 may be manufactured by material having high thermal conductivity, high durability and not responding with the metal material 255. The heating device 252 may have a structure that surrounds the crucible 251, and may provide heat to the crucible 251. Furthermore, the spray nozzle(s) 253 may control the deposition rate on the substrate S by changing a process direction of the sublimated metal material 255 sublimated or evaporated.

The first thermal ball(s) 256 and the mesh member 258 maintain a temperature at the opening of the crucible 251. The first thermal ball(s) 256 and the mesh member 258 may prevent heat from escaping to the exterior of the crucible 251. Thus, the substrate S and the mask 230, which are above the crucible 254, may not be influenced by heat from the crucible 251. Furthermore, the internal temperature of the crucible 251 may be maintained without heat loss.

The second thermal ball(s) 254 may be distributed at the bottom of the crucible 251. When the second thermal ball(s) 254 is (are) disposed between the crucible 251 and the metal material 255, a crack occurring due to the difference between thermal expansion coefficients of the crucible 251 and the metal material 255 may be prevented.

Furthermore, the second thermal ball(s) 254 is (are) formed by material having high thermal conductivity, and deliver heat to the metal material 255 constantly and stably.

As described, by depositing the metal material 255 on the substrate S using the crucible apparatus 250 including the first thermal ball(s) 256 and the second thermal ball(s) 254, the heat from the crucible 251 may be effectively delivered to the metal material 255. Thus, a uniform thickness of the metal layer may be formed.

Furthermore, the second thermal ball(s) 254 is (are) disposed between the crucible 251 and the metal material 255, a crack in the crucible 251 occurring due to the difference between thermal expansion coefficients of the crucible 251 and the metal material 255 may be prevented.

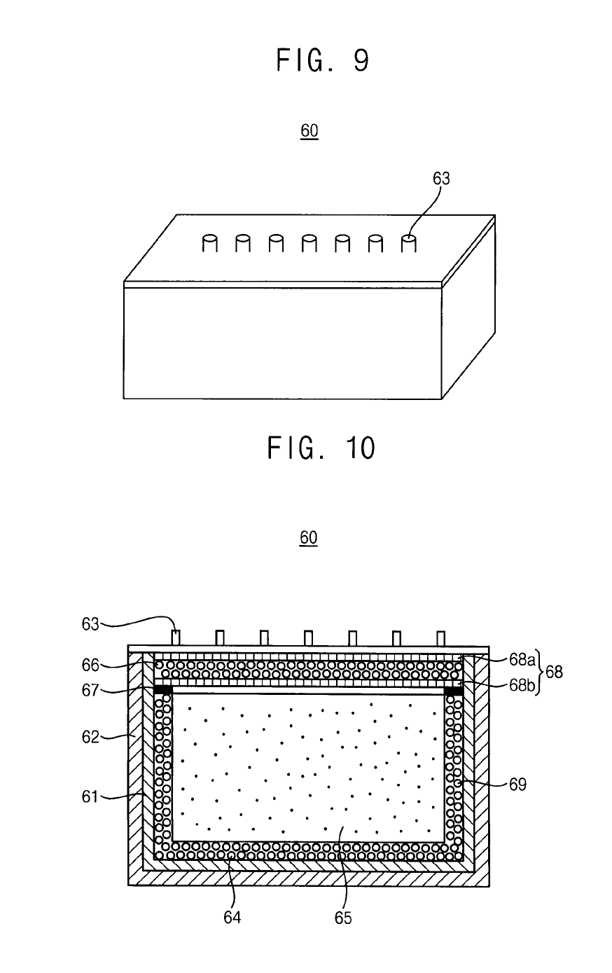

FIG. 9 is a perspective view illustrating a crucible apparatus according to an exemplary embodiment of the invention, and FIG. 10 is a cross-sectional view of the crucible apparatus illustrated in FIG. 9.

Referring to FIGS. 9 and 10, the crucible apparatus 60 may include a crucible 61, a heating device 62, spray nozzle(s) 63, first thermal ball(s) 66, second thermal ball(s) 64, third thermal ball(s) 69, a mesh member 68, and a metal material 65. The crucible apparatus 60 of FIGS. 9 and 10 has a composition similar to that of the crucible apparatus 50 of FIGS. 5 and 6 except that the third thermal ball(s) 64 is (are) additionally disposed between an inner wall of the crucible 61 and the metal material 65.

The second thermal ball(s) 64 may be distributed at the bottom of the crucible 61. The metal material 65 may be disposed on the second thermal ball(s) 64 in the crucible 61. The third thermal ball(s) 69 may be additionally distributed in a space which is formed between the metal material 65 and the inner wall of the crucible 61.

By distributing the third thermal ball(s) 69 in the space formed between the metal material 65 and the inner wall of the crucible 61, in the deposition process, the heat from the crucible 61 may be effectively delivered to the metal material 65.

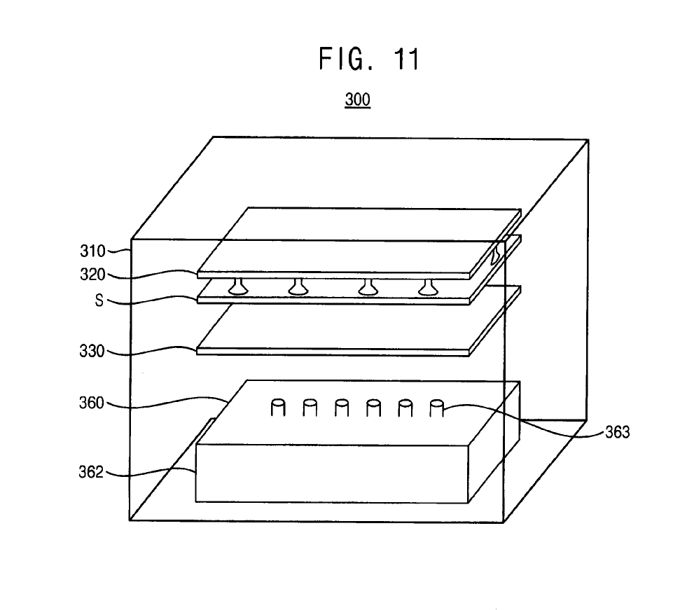

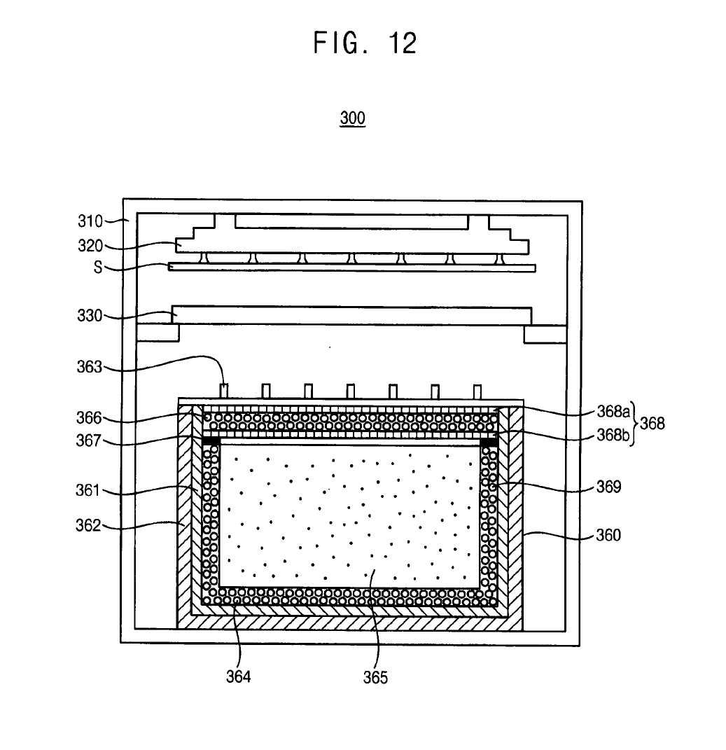

FIG. 11 is a perspective view illustrating a metal material deposition apparatus according to an exemplary embodiment of the invention, and FIG. 12 is a cross-sectional view of the metal material deposition apparatus illustrated in FIG. 11.

Referring to FIGS. 11 and 12, the metal material deposition apparatus 300 may include a deposition chamber 310, a supporting member 320, a substrate S, a mask 330 and a crucible apparatus 360. The metal material deposition apparatus 300 has composition similar to that of the metal material deposition apparatus 200 of FIGS. 7 and 8 except that the crucible apparatus 360 is changed.

The third thermal ball(s) 369 may be additionally distributed in a space which is formed between the metal material 365 and the inner wall of the crucible 361 in the crucible apparatus 360. By distributing the third thermal ball(s) 369 in the space formed between the metal material 365 and the inner wall of the crucible 361, in the deposition process, heat from the crucible 361 may be effectively delivered to the metal material 365.

As described, by depositing the metal material 365 on the substrate S using the crucible apparatus 360 including the first thermal ball(s) 366, the second thermal ball(s) 364 and the third thermal ball(s) 369, the heat from the crucible 361 may be effectively delivered to the metal material 365. Specifically, by distributing the third thermal ball(s) 369 in the space formed between the metal material 365 and the inner wall of the crucible 361, in the deposition process, the heat from the crucible 361 may be effectively delivered to the metal material 365. Thus, a uniform thickness of the metal layer may be formed.

Furthermore, the second thermal ball(s) 364 is (are) disposed between the crucible 361 and the metal material 365, a crack of the crucible 361 occurring due to the difference between thermal expansion coefficients of the crucible 361 and the metal material 365 may be prevented.

The foregoing is illustrative of the present invention, and is not to be construed as limiting thereof. Although a few exemplary embodiments of the present invention have been described, those skilled in the art will readily appreciate that many modifications are possible in the exemplary embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function, and not only structural equivalents but also equivalent structures. Therefore, it is to be understood that the foregoing is illustrative of the present invention, and is not to be construed as limited to the specific exemplary embodiments disclosed, and that modifications to the disclosed exemplary embodiments, as well as other exemplary embodiments, are intended to be included within the scope of the appended claims. The present invention is defined by the following claims, with equivalents of the claims to be included therein.

What is claimed is:

1. A crucible apparatus, comprising:
a crucible having an opening, the crucible being configured to store an organic material;
a heating device surrounding an exterior of the crucible, the heating device being configured to provide heat to the crucible;
at least one thermal ball configured to deliver the heat provided by the heating device to the organic material within the crucible so as to sublimate the organic material; and
at least one spray nozzle disposed at the opening of the crucible, said at least one spray nozzle being configured to spray the sublimated organic material.

2. The crucible apparatus of claim 1, wherein said at least one thermal ball is distributed in the crucible along with the organic material.

3. The crucible apparatus of claim 1, wherein said at least one spray nozzle is disposed on a top of the crucible; and
wherein said at least one spray nozzle is configured to move in one of a length direction and a width direction of the crucible apparatus.

4. An organic material deposition apparatus, comprising:
a deposition chamber having a space into which a substrate is inserted;
a supporting member configured to support the substrate;
a mask disposed under the substrate and configured to allow an organic material to be selectively deposited on the substrate; and
a crucible apparatus disposed opposite the substrate, the crucible apparatus including at least one thermal ball.

5. The organic material deposition apparatus of claim 4, the crucible apparatus further comprising:
a crucible having an opening, the crucible being configured to store the organic material; and
a heating device surrounding an exterior of the crucible, the heating device being configured to provide heat to the crucible;
said at least one thermal ball being configured to deliver the heat provided by the heating device to the organic material within the crucible so as to sublimate the organic material;
said crucible apparatus further comprising at least one spray nozzle disposed at the opening of the crucible, said at least one spray nozzle being configured to spray the sublimated organic material.

6. The organic material deposition apparatus of claim 5, wherein said at least one thermal ball is distributed in the crucible along with the organic material.

7. The organic material deposition apparatus of claim 5, wherein said at least one spray nozzle is disposed on top of the crucible; and
wherein said at least one spray nozzle is configured to move in one of a length direction and a width direction of the crucible apparatus.

8. A crucible apparatus, comprising:
a crucible having an opening, the crucible being configured to store a metal material;
a heating device surrounding an exterior of the crucible, the heating device being configured to provide heat to the crucible so as to sublimate the metal material;
at least one first thermal ball disposed on top of the crucible, said at least one first thermal ball being configured to maintain an internal temperature of the crucible;
a mesh member having an opening for passing the sublimated metal material, the mesh member being configured to support said at least one first thermal ball;
at least one second thermal ball disposed between the crucible and the metal material in the crucible; and
at least one spray nozzle disposed at the opening of the crucible, said at least one spray nozzle being configured to spray the sublimated metal material.

9. The crucible apparatus of claim 8, wherein said at least one second thermal ball is disposed between a bottom of the crucible and the metal material in the crucible.

10. The crucible apparatus of claim 8, further comprising at least one third thermal ball, said at least one second thermal ball being disposed between a bottom of the crucible and the metal material in the crucible, and said at least one third thermal ball being disposed between an inner wall of the crucible and the metal material in the crucible.

11. The crucible apparatus of claim 8, said at least one spray nozzle being disposed on the top of the crucible, and said at least one spray nozzle being configured to move in one of a length direction and a width direction of the crucible apparatus.

12. A metal material deposition apparatus, comprising:
a deposition chamber having a space into which a substrate is inserted;
a supporting member configured to support the substrate;
a mask disposed under the substrate and configured to allow a metal material to be selectively deposited on the substrate; and
a crucible apparatus disposed opposite the substrate, the crucible apparatus including at least one first thermal ball and at least one second thermal ball.

13. The metal material deposition apparatus of claim 13, the crucible apparatus further comprising:
a crucible having an opening, the crucible being configured to store a metal material;
a heating device surrounding an exterior of the crucible, the heating device being configured to provide heat to the crucible so as to sublimate the metal material.
said at least one first thermal ball being disposed on top of the crucible, said at least one first thermal ball being configured to maintain an internal temperature of the crucible;
the crucible apparatus comprising a mesh member having an opening for passing the sublimated metal material, the mesh member being configured to support said at least one first thermal ball;
said at least one second thermal ball being disposed between the crucible and the metal material in the crucible; and
the crucible apparatus further comprising at least one spray nozzle disposed at the opening of the crucible, said at least one spray nozzle being configured to spray the sublimated metal material.

14. The metal material deposition apparatus of claim 13, said at least one second thermal ball being disposed between a bottom of the crucible and the metal material in the crucible.

15. The metal material deposition apparatus of claim 13, further comprising at least one third thermal ball, said at least one second thermal ball being disposed between a bottom of the crucible and the metal material in the crucible, said at least one third thermal ball being disposed between an inner wall of the crucible and the metal material in the crucible.

16. The metal material deposition apparatus of claim 13, wherein said at least one spray nozzle is disposed on top of the crucible; and
wherein said at least one spray nozzle is configured to move in one of a length direction and a width direction of the crucible apparatus.
